(19) United States
(12) Patent Application Publication
(10) Pub. No.: US 2025/0365860 A1
(43) Pub. Date: Nov. 27, 2025

(54) COPPER-CLAD LAMINATE AND USES OF THE SAME

(71) Applicant: TAIWAN UNION TECHNOLOGY CORPORATION, Zhubei City (TW)

(72) Inventor: Yun-Hsing SUNG, Zhubei City (TW)

(21) Appl. No.: 18/975,105

(22) Filed: Dec. 10, 2024

(30) Foreign Application Priority Data
May 24, 2024 (TW) 113119382

(51) Int. Cl. H05K 1/03

(52) U.S. Cl. CPC H05K 1/032; H05K 2201/0355

(57) ABSTRACT

A copper-clad laminate is provided. The copper-clad laminate comprises a dielectric layer; and at least one copper foil which has a first surface. The copper foil is disposed on at least one side of the dielectric layer, and is adhered to the dielectric layer with the first surface. The copper foil has a zinc content ranging from 40 μg/dm² to 450 μg/dm², a nickel content ranging from 10 μg/dm² to 30 μg/dm², and a chromium content of no more than 1 μg/dm² at the first surface.

### CLAIM FOR PRIORITY

This application claims the benefit of Taiwan Patent Application No. 113119382 filed on May 24, 2024, the subject matters of which are incorporated herein in their entirety by reference.

### BACKGROUND OF THE INVENTION

### Field of the Invention

The present invention provides a copper clad laminate, especially a copper clad laminate with specific zinc and nickel contents and low chromium content. The present invention also provides a printed circuit board prepared using the copper clad laminate.

### Descriptions of the Related Art

Portable electronic products are continuously advancing toward higher functionality and must be capable of processing large amounts of information at high speeds. Consequently, the base station signals are also becoming higher in frequency, leading to increasing attention on printed circuit boards suitable for high-frequency applications. In order to transmit signals without compromising the quality of high-frequency signals, the industry is focused on reducing the high-frequency transmission loss in printed circuit boards, especially those designed for high-frequency transmission, such as millimeter-wave radar boards.

The transmission loss of printed circuit boards can be primarily divided into two parts. One part arises from the conductor loss of the copper foil, and the other part arises from the dielectric loss of the insulating resin substrate. To reduce the dielectric loss of the insulating resin substrate, thermosetting resins with low dielectric constant and low dielectric loss (such as polyphenylene ether resin) are commonly used in the market. However, conventional resins with low dielectric constant and low dielectric loss usually exhibit poor adhesion to copper foil.

The reason for the above problem lies in the fact that low-dielectric resins are typically low-polarity and have molecular structures that make it difficult to generate oriented polarization. This results in weaker intermolecular forces at the interface between the insulating resin substrate and the copper foil, making it difficult to achieve chemical adhesion. To enhance the adhesion at the interface between the insulating resin substrate and the copper foil, prior art suggests altering the surface of the copper foil to create an anchoring effect. For example, techniques such as the “attachment of fine copper grains” disclosed in JP H05-029740 or “concave-convex formation via etching” disclosed in JP 2000-282265 A are used for surface roughening. However, during the signal transmission process, the signal depth becomes shallower as the frequency increases and tends to propagate near the copper foil surface (i.e., skin effect). Therefore, if the copper foil surface undergoes such surface roughening treatment, the signal will follow along the irregularities of the copper foil surface, causing the transmission distance to increase.

To address the issue of increased signal transmission distance, prior art attempts to improve the situation by reducing the conductor resistance of the copper foil, such as by reducing the surface roughness of the original copper foil or by lowering the degree of surface roughening. However, reducing the degree of roughening would decrease the anchoring effect, which in turn weakens the physical adhesion between the insulating resin substrate and copper foil.

Therefore, there is still a need for a copper foil laminate that combines good adhesion, low dielectric properties and excellent signal transmission integrity, suitable for various high-frequency applications, including millimeter-wave applications.

### SUMMARY OF THE INVENTION

The inventors found that by controlling the content of zinc, nickel and chromium at the surface of copper foil in contact with the dielectric layer, the resulting copper-clad laminate can exhibit good peeling strength, chemical resistance, infrared reflow resistance, and signal integrity, making it especially suitable for high-frequency signal transmission.

Thus, an objective of the present invention is to provide a copper clad laminate, which comprises:
a dielectric layer; and
at least one copper foil which has a first surface,
wherein the copper foil is disposed on at least one side of the dielectric layer, the copper foil is adhered to the dielectric layer with the first surface, and the copper foil has a zinc content ranging from 40 μg/dm² to 450 μg/dm², a nickel content ranging from 10 μg/dm² to 30 μg/dm², and a chromium content of no more than 1 μg/dm² at the first surface.

In one embodiment of the present invention, the copper foil has a zinc content ranging from g/dm² to 150 μg/dm² at the first surface.

In one embodiment of the present invention, the copper foil has a chromium content of no more than 0.5 μg/dm² at the first surface.

In one embodiment of the present invention, the first surface has a ten-point average roughness (Rz) of less than 0.5 μm.

In one embodiment of the present invention, the copper foil is disposed on each side of the dielectric layer and adhered to the dielectric layer with its first surface.

In one embodiment of the present invention, the dielectric layer comprises a dielectric material formed from a resin composition.

In one embodiment of the present invention, the resin composition is a thermosetting resin composition.

In one embodiment of the present invention, the thermosetting resin composition comprises a thermosetting component selected from the group consisting of an epoxy resin, a thermosetting phenolic resin, a thermosetting benzoxazine resin (hereinafter “thermosetting BZ resin”), a thermosetting polyphenylene ether resin, a thermosetting multi-functional vinyl aromatic copolymer, a thermosetting nitrogen-containing heterocyclic copolymer, and combinations thereof.

In one embodiment of the present invention, the resin composition further comprises a component selected from the group consisting of a hardener, a catalyst, an elastomer, a filler, a dispersing agent, a toughener, a viscosity modifying agent, a flame retardant, a coupling agent, and combinations thereof.

Another objective of the present invention is to provide a printed circuit board, which is prepared from the aforementioned copper clad laminate.

To render the above objectives, technical features and advantages of the present invention more apparent, the present invention will be described in detail with reference to some embodiments hereinafter.

### BRIEF DESCRIPTION OF THE DRAWINGS

Not applicable.

### DESCRIPTION OF THE PREFERRED EMBODIMENTS

Hereinafter, some embodiments of the present invention will be described in detail. However, the present invention may be embodied in various embodiments and should not be limited to the embodiments described in the specification.

Unless otherwise specified, the expressions “a,” “the,” or the like recited in the specification and in the claims should include both the singular and the plural forms.

Unless otherwise specified, the expressions “first”, “second” or the like recited in this specification and claims are solely for distinguishing the described elements or components and do not imply any special meanings or any particular order.

Unless otherwise specified, when the amount of the components in a solution, mixture, composition or varnish are described in the specification and the claims, the weight of the solvent is not included in the calculation.

As used herein, the material of the “copper foil” is copper with a purity of 99.5% or more.

The copper clad laminate of the present invention is obtained by combining copper foil with a dielectric layer, where the copper foil has specific contents of zinc, nickel and chromium at its first surface (the surface in contact with a dielectric layer). This combination results in improved peeling strength, chemical resistance, infrared reflow resistance, and signal integrity.

Further details about the copper clad laminate and its applications are elaborated below.

### 1. Copper Clad Laminate

The copper clad laminate of the present invention comprises a dielectric layer and at least one copper foil. The copper foil is disposed on at least one side of the dielectric layer, preferably on both sides of the dielectric layer. In one embodiment of the present invention, the copper clad laminate essentially consists of the dielectric layer and the at least one copper foil, or the copper clad laminate consists of the dielectric layer and the at least one copper foil.

### 1.1. Copper Foil

The copper foil of the copper clad laminate of the present invention has a first surface, and the copper foil is adhered to the dielectric layer with the first surface. The copper foil has a zinc content ranging from 40 μg/dm² to 450 μg/dm², a nickel content ranging from 10 μg/dm² to 30 μg/dm², and a chromium content of no more than 1 μg/dm² at the first surface. In one embodiment of the present invention, the copper foil is a copper foil that is not subjected to a surface roughening treatment.

### 1.1.1. Type and Material of Copper Foil

Previously, the copper foil used in rigid substrates was electrodeposited copper foil, while copper foils used in flexible substrates was rolled annealed copper foil. However, with the development of flexible substrates, electro-deposited copper foil with properties similar to those of rolled annealed copper foil has been developed. Thus, there are no specific limitations on the type of copper foil that can be used in the copper clad laminate of the present invention. It can be any type of copper foil, including electro-deposited copper foil and rolled annealed copper foil.

Electro-deposited copper foil is typically manufactured by electrolytically depositing copper from a copper sulfate plating bath onto a titanium or stainless drum. Rolled annealed copper foil, on the other hand, is typically manufactured by repeatedly subjecting copper ingots to plastic deformation and heat treatment using a calendar roll. The material of the copper foil includes, but is not limited to, refined copper (JIS H3100 alloy number C1100), oxygen-free copper (JIS H3100 alloy number C1020 or JIS H3510 alloy number C1011), phosphorus deoxidized copper (JIS H3100 alloy number C1201, C1220 or C1221), and electrolytic copper. In addition, the copper foil can optionally comprise 30 ppm to 300 ppm of one or more elements selected from the group consisting of P, B, Ti, Mn, V, Cr, Mo, Ag, Sn, In, Au, Pd, Zn, Ni, Si, Zr, and Mg. Examples of the copper foil containing other elements include, but are not limited to, Sn-doped copper, Ag-doped copper, Cr-added copper alloy, Zr-added copper alloy, Mg-added copper alloy, and corson-based copper alloy that is added with Ni and Si.

In addition, to enhance the copper foil's rust inhibition, dielectric properties, thermal resistance and chemical resistance, and enhance its adhesion to dielectric materials, appropriate surface treatments can be applied to the copper foil. These surface treatments include, but are not limited to, a roughening treatment, a thermal-resistance enhancement, a rust-prevention treatment, a chromate treatment, and a silane-coupling treatment. In some embodiments of the present invention, the copper foil may undergo one or more of the aforementioned surface treatments, as long as the first surface of the treated copper foil still has a zinc content ranging from 40 μg/dm² to 450 μg/dm², a nickel content ranging from 10 μg/dm² to 30 μg/dm², and a chromium content of no more than 1 μg/dm².

### 1.1.2. Properties of Copper Foil

The copper foil of the copper clad laminate of the present invention contains specific metal elements in a certain content at the first surface. Specifically, the copper foil has a zinc content ranging from 40 μg/dm² to 450 μg/dm² at the first surface. For example, the zinc content at the first surface of the copper foil can be 40 μg/dm², 50 μg/dm², 60 μg/dm², 70 μg/dm², 80 μg/dm², 90 μg/dm², 100 μg/dm², 110 μg/dm², 120 μg/dm², 130 μg/dm², 140 μg/dm², 150 μg/dm², 160 μg/dm², 170 μg/dm², 180 μg/dm², 190 μg/dm², 200 μg/dm², 210 μg/dm², 220 μg/dm², 230 μg/dm², 240 μg/dm², 250 μg/dm², 260 μg/dm², 270 μg/dm², 280 μg/dm², 290 μg/dm², 300 μg/dm², 310 μg/dm², 320 μg/dm², 330 μg/dm², 340 μg/dm², 350 μg/dm², 360 μg/dm², 370 μg/dm², 380 μg/dm², 390 μg/dm², 400 μg/dm², 410 μg/dm², 420 μg/dm², 430 μg/dm², 440 μg/dm², or 450 μg/dm², or within a range between any two of the values described herein. In the preferred embodiments of the present invention, the copper foil has a zinc content ranging from 40 μg/dm² to 150 μg/dm² at the first surface.

In addition, the copper foil has a nickel content ranging from 10 μg/dm² to 30 μg/dm² at the first surface. For example, the nickel content at the first surface of the copper foil can be 10 μg/dm², 11 μg/dm², 12 μg/dm², 13 μg/dm², 14 μg/dm², 15 μg/dm², 16 μg/dm², 17 μg/dm², 18 μg/dm², 19 μg/dm², 20 μg/dm², 21 μg/dm², 22 μg/dm², 23 μg/dm², 24 μg/dm², 25 μg/dm², 26 μg/dm², 27 μg/dm², 28 μg/dm², 29 μg/dm², or 30 μg/dm², or within a range between any two of the values described herein.

Furthermore, the copper foil has a chromium content of no more than 1 μg/dm² at the first surface. For example, the chromium content at the first surface of the copper foil can be 1 μg/dm², 0.9 μg/dm², 0.8 μg/dm², 0.7 μg/dm², 0.6 μg/dm², 0.5 μg/dm², 0.4 μg/dm², 0.3 μg/dm², 0.2 μg/dm², 0.1 μg/dm², or 0 μg/dm², or within a range between any two of the values described herein. In the preferred embodiments of the present invention, the chromium content at the first surface of the copper foil is greater than 0 μg/dm² and no more than 0.5 μg/dm².

The testing method for the content of zinc, nickel, and chromium is as follows. First, the copper foil is cut into 10 cm×10 cm test samples, and transparent tape is used to cover the non-measurement side (i.e., the second surface, not the first surface). Next, the test sample is laid flat in a glass container with the first surface facing up. A 100 ml of nitric acid solution with a weight percent concentration of 21% (composition: nitric acid and water) is poured into the glass container, ensuring that the liquid level covers the test sample. After soaking at room temperature for 30 seconds, the test sample is removed and analyzed using ICP (inductively coupled plasma) emission spectrometry to measure the content of zinc, nickel and chromium in the nitric acid solution. The same test is conducted on three test samples, and the average value is taken to determine the content of zinc, nickel, and chromium at the surface of the copper foil.

In the preferred embodiments of the present invention, the first surface of the copper foil has a ten-point average roughness (Rz) of less than 0.5 μm. For example, the Rz of the first surface of the copper foil of the present invention can be 0.49 μm, 0.48 μm, 0.47 μm, 0.46 μm, 0.48 μm, 0.44 μm, 0.43 μm, 0.42 μm, 0.41 μm, 0.40 μm, 0.39 μm, 0.38 μm, 0.37 μm, 0.36 μm, 0.35 μm, 0.34 μm, 0.33 μm, 0.32 μm, 0.31 μm, 0.30 μm, 0.29 μm, 0.28 μm, 0.27 μm, 0.26 μm, 0.25 μm, 0.24 μm, 0.23 μm, 0.22 μm, 0.21 μm, 0.20 μm, 0.19 μm, 0.18 μm, 0.17 μm, 0.16 μm, 0.15 μm, 0.14 μm, 0.13 μm, 0.12 μm, 0.11 μm, 0.10 μm, 0.09 μm, 0.08 μm, 0.07 μm, 0.06 μm, 0.05 μm, 0.04 μm, 0.03 μm, 0.02 μm, 0.01 μm, or 0 μm, or within a range between any two of the values described herein. The Rz is measured in accordance with JIS B0601:2001 standard using a contact-type surface roughness meter, with a probe diameter of 2 μm.

The thickness of the copper foil is not particularly limited, but preferably ranging from 2 μm to 80 μm. For example, the thickness of the copper foil can be 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, or 80 μm, or within a range between any two of the values described herein. As used herein, the thickness of the copper foil refers to a weight average thickness obtained by dividing the areal weight of the copper foil (grams per unit area, square meters) by the density of the copper foil (grams per cubic meters).

### 1.1.3. Preparation of Copper Foil

The copper foil can be manufactured by the following method, but the present invention is not limited thereto. First, a copper electrolyte solution containing copper ions (Cu²⁺) ranging from 40 μg/L to 150 μg/L, sulfuric acid (H₂SO₄) from 40 μg/L to 200 μg/L and chloride ions (Cl⁻) from 1 (one) ppm to 30 ppm is prepared. Next, the copper electrolyte solution is introduced into a raw foil electrolysis equipment equipped with a rotatable cathode roll and an insoluble anode. A current with a current density of 30 A/dm² to 60 A/dm² is applied to the cathode roll and the insoluble anode, respectively. The copper electrolyte solution is maintained at a temperature of 50° C. to 58° C., and a raw foil is obtained and continuously wound onto a guiding roll. Next, the raw foil is conveyed into a continuous surface treatment device at a transport speed of 16 m/min via multiple guiding rolls. The continuous surface treatment device includes roughening treatment tank 1, roughening treatment tank 1A, curing treatment tank 2, curing treatment tank 3, roughening treatment tank 4, roughening treatment tank 5, curing treatment tank 6, curing treatment tank 7, nickel-plating treatment tank 8, zinc-plating treatment tank 9, acid treatment tank 10, pure water treatment tank 10A, and silane treatment tank 11. In one embodiment of the present invention, only the roughening treatment tank 1A and curing treatment tank 3 are not energized, while the other tanks—roughening treatment tank 1, curing treatment tank 2, roughening treatment tank 4, roughening treatment tank 5, curing treatment tank 6, curing treatment tank 7, nickel-plating treatment tank 8, and zinc-plating treatment tank 9—are energized, and the acid treatment tank 10, pure water treatment tank 10A, and silane treatment tank 11 are activated for immersion or rinsing treatment. In other words, the raw foil is only immersed in the solutions (such as electroplating solutions) in the unpowered roughening treatment tank 1A and curing treatment tank 3 without undergoing relevant treatments. The raw foil undergoes the corresponding treatments when passing through the energized or activated roughening treatment tank 1, curing treatment tank 2, roughening treatment tank 4, roughening treatment tank 5, curing treatment tank 6, curing treatment tank 7, nickel-plating treatment tank 8, zinc-plating treatment tank 9, acid treatment tank 10, pure water treatment tank 10A, and silane treatment tank 11. Therefore, the raw foil subsequently undergoes one roughening treatment, one curing treatment, one roughening treatment, one roughening treatment, one curing treatment, one curing treatment, one nickel-plating treatment, one zinc-plating treatment, one chromic acid treatment, one pure water treatment, and one silane treatment in sequence. This process results in a lowly-roughened electro-deposited copper foil with a thickness of 18 μm and an Rz of less than 0.5 μm at the first surface. The parameters of the continuous surface treatment tanks are listed in Tables 1-1 and 1-2. The treatment solution used in treatment tank 11 contains (3-epoxypropoxypropyl)trimethoxysilane as the silane coupling agent, with a concentration of 5 g/L to 7 g/L, and water is used as the solvent for the treatment solution. In addition, as understood by persons having ordinary skill in the art, the electroplating time can be calculated based on the transport speed of the raw foil, the effective anode plate length, and the effective anode plate depth, so the electroplating time, and is not elaborated further here.

TABLE 1-1
Parameters for continuous surface treatment tanks

| Number of | Type of | | Concentration of | Content of | | Concentration of | Manner of |
|---|---|---|---|---|---|---|---|
| treatment | surface | Metal | metal ion | fluorine | Type of | acid/base | surface |
| tank | treatment | ion | (g/L) | (ppm) | acid/base | (g/L) | treatment |
| 1 | Roughening | Cu²⁺ | 5.0 to 10 | 0 to 3 | Sulfuric acid | 90 to 100 | Plating |
| 1A | Roughening | Cu²⁺ | 5.0 to 10 | 0 to 3 | Sulfuric acid | 90 to 100 | Plating |
| 2 | Curing | Cu²⁺ | 66 to 80 | 0 to 3 | Sulfuric acid | 60 to 75 | Plating |
| 3 | Curing | Cu²⁺ | 66 to 80 | 0 to 3 | Sulfuric acid | 60 to 75 | Plating |
| 4 | Roughening | Cu²⁺ | 5.0 to 10 | 0 to 3 | Sulfuric acid | 90 to 100 | Plating |
| 5 | Roughening | Cu²⁺ | 5.0 to 10 | 0 to 3 | Sulfuric acid | 90 to 100 | Plating |
| 6 | Curing | Cu²⁺ | 66 to 80 | 0 to 3 | Sulfuric acid | 60 to 75 | Plating |
| 7 | Curing | Cu²⁺ | 66 to 80 | 0 to 3 | Sulfuric acid | 60 to 75 | Plating |
| 8 | Ni plating*¹ | Ni²⁺ | 17 to 20 | 0 to 3 | Phosphoric | 3 to 6 | Plating |
| | | | | | acid | | |
| 9 | Zn plating | Zn²⁺ | 2 to 4 | 0 to 3 | Boric acid | 10 to 25 | Plating |
| 10 | Chromic | Cr⁶⁺ | 10⁻⁴ to 10⁻³ | 0 to 3 | Phosphoric | 0.1 to 2.0 | Immersing |
| | acid and | | | | acid | | |
| | phosphoric | | | | | | |
| | acid*¹ | | | | | | |
| 10A | Pure water | None | None | 0 to 3 | None | None | Rinsing |
| 11 | Silane | None | None | 0 to 3 | None | None | Immersing |

*¹In some embodiments of the present invention, the solution in treatment tank 10 is pure water.

TABLE 1-2
Parameters for continuous surface treatment tanks

| Number of | Trace | Temperature of | pH of | Effective anode | Effective anode |
|---|---|---|---|---|---|
| treatment | component^{*2} | treatment tank ^{*3} | treatment | plate length | plate depth |
| tank | (ppm) | (° C.) | tank | (decimeter) | (decimeter) |
| 1 | 180 to 220 | 30 | <1.5 | 14 | 3.47 |
| 1A | 180 to 220 | 30 | <1.5 | 14 | 3.47 |
| 2 | 30 to 40 | 45 | <1.5 | 14 | 5.87 |
| 3 | 30 to 40 | 45 | <1.5 | 14 | 5.87 |
| 4 | 180 to 220 | 30 | <1.5 | 14 | 3.47 |
| 5 | 180 to 220 | 30 | <1.5 | 14 | 3.47 |
| 6 | 30 to 40 | 45 | <1.5 | 14 | 5.87 |
| 7 | 30 to 40 | 45 | <1.5 | 14 | 5.87 |
| 8 | 100 to 200 | 28 | 3 to 4 | 14 | 2.00 |
| 9 | 100 to 200 | 30 | 4 to 5 | 14 | 4.00 |
| 10 | 100 to 200 | 40 | 3 to 4 | Not applicable | Not applicable |
| 10A | None | 40 | 6.5 to 7 | Not applicable | Not applicable |
| 11 | 0 to 20 | 40 | Not applicable | Not applicable | Not applicable |

^{*2}Examples of the trace component include, but are not limited to, Ni, Pd, Ag and W.
^{*3} The tolerance of the temperature of the treatment tank is ±5° C.

In addition, in treatment tanks 9, 10 and 10A, trace components may be present in the electroplating solution in the form of SO₄²⁻, HSO₄⁻, PO₄³⁻, HPO₄²⁻, H₂PO⁴⁻ and others. The zinc, nickel and chromium contents at the first surface of the copper foil can be adjusted by controlling the current magnitude in treatment tanks 8 and 9, the immersion time in treatment tank 10, and the rinsing time in treatment tank 10A. Specifically, the zinc, nickel and chromium contents at the first surface of the copper foil can be adjusted by controlling the current during electroplating (in amperes), the immersion time (in seconds), and the rinsing time (in seconds). Generally, a higher electroplating current, longer immersion time, and shorter rinsing time result in a higher content of the corresponding plated elements. Conversely, lower electroplating current, shorter immersion time, and longer rinsing time lead to lower element content.

### 1.2. Dielectric Layer

The dielectric layer of the copper clad laminate of the present invention comprises a dielectric material formed from a resin composition. Alternatively, the dielectric layer essentially consists of or consists of the dielectric material. The dielectric material can be manufactured by drying the resin composition to form a resin sheet. The method for preparing the resin sheet is not particularly limited and can follow conventional resin sheet manufacturing processes.

In one embodiment of the present invention, the resin sheet comprises one or more reinforcing materials. A reinforcing material-comprising resin sheet can be manufactured by impregnating a reinforcing material with the resin composition or by coating the resin composition onto a reinforcing material, and then drying the impregnated or coated reinforcing material. The impregnating and coating methods include but are not limited to dipping, roller coating, die coating, bar coating, and spraying. The drying conditions can be at a temperature of 170° C. to 250° C. for a duration of 2 minutes to 15 minutes.

### 1.2.1. Reinforcing Material

The reinforcing material can be any reinforcing material known in the field to which the present invention pertains. Generally, the reinforcing material may include fibers selected from the group consisting of glass fibers, inorganic fibers other than glass fiber, and organic fiber. However, the reinforcing material is not limited to these categories. Examples of glass fibers include, but are not limited to, E-glass fibers, NE-glass fibers, S-glass fibers, L-glass fibers, D-glass fibers, T-glass fibers, Q-glass fibers, UN-glass fibers, and spherical glass. Examples of inorganic fibers other than glass fibers include, but are not limited to, quartz fibers. Examples of organic fibers include, but are not limited to, polyimide, polyamide, polyester, liquid crystal polyester, and polytetrafluoroethylene. The aforementioned materials can be used individually or in a mixture of two or more. The shape of the reinforcing material includes various forms such as woven fabric, non-woven fabric, roving, chopped strand mat, and surfacing mat, among others. For enhanced dimensional stability, preference is given to fabrics treated with super fiber opening and leveling processes as the reinforcing material. For enhanced moisture absorption thermal resistance, preference is given to glass fiber woven fabrics treated with surface treatment such as epoxy silane treatment, silane coupling agent treatment, and the like, as the reinforcing material. For enhanced electrical properties, preference is given to low-dielectric glass fiber fabrics as the reinforcing material. Examples of such low-dielectric glass fiber fabrics include glass fiber fabrics consist of glass fibers like L-glass, NE-glass, Q-glass, and similar variants.

The thickness of the dielectric layer is not particularly limited. Generally, the thickness of the dielectric layer can be 310 μm or less, preferably ranging from 250 μm to 310 μm. For example, the thickness of the dielectric layer can be 250 μm, 251 μm, 252 μm, 253 μm, 254 μm, 255 μm, 256 μm, 257 μm, 258 μm, 259 μm, 260 μm, 261 μm, 262 μm, 263 μm, 264 μm, 265 μm, 266 μm, 267 μm, 268 μm, 269 μm, 270 μm, 271 μm, 272 μm, 273 μm, 274 μm, 275 μm, 276 μm, 277 μm, 278 μm, 279 μm, 280 μm, 281 μm, 282 μm, 283 μm, 284 μm, 285 μm, 286 μm, 287 μm, 288 μm, 289 μm, 290 μm, 291 μm, 292 μm, 293 μm, 294 μm, 295 μm, 296 μm, 297 μm, 298 μm, 299 μm, 300 μm, 301 μm, 302 μm, 303 μm, 304 μm, 305 μm, 306 μm, 307 μm, 308 μm, 309 μm, or 310 μm, or within a range between any two of the values described herein.

### 1.2.2. Resin Composition

In the copper clad laminate of the present invention, the resin composition for forming the dielectric material can comprise thermosetting component(s). When the resin composition comprises thermosetting component(s), it is referred to as a thermosetting resin composition. In addition, the resin composition for forming the dielectric material can optionally comprise additive(s) to adaptively improve the workability of the resin composition during processing or improve the physicochemical properties of the electronic material prepared from the resin composition.

### 1.2.2.1. Thermosetting Component

A thermosetting component refers to a thermosetting resin which has reactive functional groups and is gradually cured after being heated to form a network structure through a crosslinking reaction. The reactive functional groups refer to functional groups cable of conducting a curing reaction with other groups. Examples of reactive functional groups include, but are not limited to, hydroxyl, carboxyl, alkenyl, and amino groups. Examples of thermosetting resin include, but are not limited to, an epoxy resin, a thermosetting phenolic resin, a thermosetting benzoxazine resin, a thermosetting polyphenylene ether resin, a thermosetting multi-functional vinyl aromatic copolymer, and a thermosetting nitrogen-containing heterocyclic copolymer. The aforementioned thermosetting resins can be used individually or in a mixture of two or more. In one embodiment of the present invention, a thermosetting polyphenylene ether resin, a thermosetting nitrogen-containing heterocyclic copolymer or a combination thereof are used as the thermosetting resin.

### [Thermosetting Polyphenylene Ether Resin]

As used herein, a thermosetting polyphenylene ether resin refers to a resin with at least a repeating unit

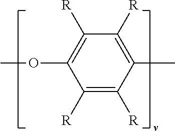

in the main chain and an unsaturated group at the terminal, wherein each R is independently H or a C1-C5 alkyl, and v is an integer ranging from 1 to 100. The unsaturated group refers to a group capable of undergoing addition polymerization with other components containing unsaturated groups. The addition polymerization reaction can be initiated by light or heat in the presence of a polymerization initiator. Examples of the unsaturated group include but are not limited to vinyl, vinyl benzyl, allyl, acrylate group, and methacrylate group. Examples of the thermosetting polyphenylene ether resin include but are not limited to a vinyl-containing polyphenylene ether resin, an allyl-containing polyphenylene ether resin, a vinyl benzyl-containing polyphenylene ether resin, an acrylate group-containing polyphenylene ether resin, and a methacrylate group-containing polyphenylene ether resin. The aforementioned polyphenylene ether resins can be used individually or in a mixture of two or more.

The method for preparing the thermosetting polyphenylene ether resin is not the technical feature of the present invention. It can be carried out by persons having ordinary skill in the art based on the present disclosure and their ordinary skill. Therefore, it is not elaborated further here. The associated methods for preparing the polyphenylene ether resin can be found in various references, including U.S. Pat. No. 6,995,195 B2 for vinyl benzyl-containing polyphenylene ether resins, U.S. Pat. No. 5,218,030 A for allyl-containing polyphenylene ether resins, U.S. Pat. No. 5,352,745 A for methacrylate group-containing polyphenylene ether resins, U.S. Pat. No. 6,352,782 B2 and US 2016/0280913 A1. These references are incorporated herein in their entireties by reference.

Examples of commercially available thermosetting polyphenylene ether resin include products such as OPE-2st 1200 and OPE-2st 2200 available from MITSUBISHI GAS CHEMICAL Company, SA-9000 available from SABIC Company, PP807 available from Chin Yee Chemical Industry Company, and polyphenylene ether products available from ASAHI KASEI Company.

The amount of the thermosetting polyphenylene ether resin can be adjusted depending on the need. Generally, based on the total weight of the resin composition, the amount of the thermosetting polyphenylene ether resin can be 15 wt % to 60 wt %. For example, based on the total weight of the resin composition, the amount of the thermosetting polyphenylene ether resin can be 15 wt %, 20 wt %, 25 wt %, 30 wt %, 35 wt %, 40 wt %, 45 wt %, 50 wt %, 55 wt %, or 60 wt %, or within a range between any two of the values described herein.

### [Thermosetting Nitrogen-Containing Heterocyclic Copolymer]

As used herein, a thermosetting nitrogen-containing heterocyclic copolymer refers to a nitrogen-containing heterocyclic copolymer which has reactive functional groups. The method for preparing the thermosetting nitrogen-containing heterocyclic copolymer is not the technical feature of the present invention. It can be carried out by persons having ordinary skill in the art based on the present disclosure and their ordinary skill. For example, the thermosetting nitrogen-containing heterocyclic copolymer can be obtained by reacting a Q-moiety-containing monomer, an X-moiety-containing monomer, and a Y-moiety-containing monomer in the presence of an alkali metal or an alkali metal compound in an organic solvent. Alternatively, the thermosetting nitrogen-containing heterocyclic copolymer can be obtained by first reacting a Q-moiety-containing monomer with an X-moiety-containing monomer and then reacting the product with a Y-moiety-containing monomer in the presence of an alkali metal or an alkali metal compound in an organic solvent.

Examples of the Q-moiety-containing monomer include, but are not limited to, a pyrimidine compound, a pyridazine compound, and a pyrazine compound. The aforementioned Q-moiety-containing monomer can be used individually or in a mixture of two or more. Examples of the pyrimidine compound include, but are not limited to, 4,6-dichloropyrimidine, 4,6-dibromopyrimidine, 2,4-dichloropyrimidine, 2,5-dichloropyrimidine, 2,5-dibromopyrimidine, 5-bromo-2-chloropyrimidine, 5-bromo-2-fluoropyrimidine, 5-bromo-2-iodopyrimidine, 2-chloro-5-fluoropyrimidine, 2-chloro-5-iodopyrimidine, 2-phenyl-4,6-dichloropyrimidine, 2-methylthio-4,6-dichloropyrimidine, 2-methylsulfonyl-4,6-dichloropyrimidine, 5-methyl-4,6-dichloropyrimidine, 2-amino-4,6-dichloropyrimidine, 5-amino-4,6-dichloropyrimidine, 2,5-diamino-4,6-dichloropyrimidine, 4-amino-2,6-dichloropyrimidine, 5-methoxy-4,6-dichloropyrimidine, 5-methoxy-2,4-dichloropyrimidine, 2-methyl-4,6-dichloropyrimidine, 6-methyl-2,4-dichloropyrimidine, 5-methyl-2,4-dichloropyrimidine, 5-nitro-2,4-dichloropyrimidine, 4-amino-2-chloro-5-fluoropyrimidine, 2-methyl-5-amino-4,6-dichloropyrimidine, and 5-bromo-4-chloro-2-(methylthio)pyrimidine. Examples of the pyridazine compound include, but are not limited to, 3,6-dichloropyridazine, 3,5-dichloropyridazine, and 4-methyl-3,6-dichloropyridazine. Examples of the pyrazine compound include, but are not limited to, 2,3-dichloropyrazine, 2,6-dichloropyrazine, 2,5-dibromopyrazine, 2,6-dibromopyrazine, 2-amino-3,5-dibromopyrazine, and 5,6-dicyano-2,3-dichloropyrazine.

Examples of the X-moiety-containing monomer include, but are not limited to, a dihydroxyphenyl compound, a bisphenol compound, and a diol compound. The aforementioned X-moiety-containing monomer can be used individually or in a mixture of two or more. Examples of the dihydroxyphenyl compound include, but are not limited to, p-benzenediol, m-benzenediol, o-benzenediol, and phenyl p-benzenediol. Examples of the bisphenol compound include, but are not limited to, 9,9-bis(4-hydroxyphenyl)fluorene, 9,9-bis(4-hydroxy-3-methylphenyl)fluorene, 9,9-bis(4-hydroxy-3-phenylphenyl)fluorene, 1,1-bis(4-hydroxyphenyl)-1-phenylethane, bis(4-hydroxyphenyl)diphenylmethane, 2,2-bis(4-hydroxyphenyl)propane, 2,2-bis(4-hydroxy-3-allylphenyl)propane, 2,2-bis(4-hydroxy-3-methylphenyl)propane, 2,2-bis(4-hydroxy-3-phenylphenyl)propane, 4,4′-(1,3-dimethylbutylidene)bisphenol, 1,1-bis(4-hydroxyphenyl)-nonane, bis(4-hydroxyphenyl)sulfone, 1,1-bis(4-hydroxyphenyl)cyclohexane, 1,1-bis(4-hydroxyphenyl)-3,3,5-trimethylcyclohexane, 1,1-bis(3-methyl-4-hydroxyphenyl)-3,3,5-trimethylcyclohexane, 1,1-bis(3-cyclohexyl-4-hydroxyphenyl)-3,3,5-trimethylcyclohexane, 1,4-bis[2-(4-hydroxyphenyl)-2-propyl]benzene, 1,3-bis[2-(4-hydroxyphenyl)-2-propyl]benzene, 4,4′-(cyclododecylidene)diphenol, and 4,4′-decylidenebisphenol. Examples of the diol compound include, but are not limited to, products PRIPLAST 1901, PRIPLAST 1838, PRIPLAST 3186, PRIPLAST 3192, PRIPLAST 3197, and PRIPLAST 3199 available from Croda Japan.

Examples of the Y-moiety-containing monomer include, but are not limited to, a monophenol compound, an aliphatic halide, an acid halide, an anhydride, and an unsaturated alcohol. The aforementioned Y-moiety-containing monomer can be used individually or in a mixture of two or more. Examples of the monophenol compound include, but are not limited to, 4-isopropenylphenol, 3-isopropenyl phenol, 2-isopropenyl phenol, 4-vinylphenol, 2-allylphenol, 3-allylphenol, and 4-allylphenol. Allyl chloride is one of the examples of the aliphatic halide, but the present invention is not limited thereto. Examples of the acid halide include, but are not limited to, acryloyl chloride and methacryloyl chloride. Examples of the anhydride include, but are not limited to, acrylic anhydride and methacrylic anhydride. Examples of the unsaturated alcohol include, but are not limited to, (4-vinylphenyl)methanol, (3-vinylphenyl)methanol, and (2-vinylphenyl)methanol.

Examples of the organic solvent include, but are not limited to, tetrahydrofuran (THF), dioxane, cyclopentyl methyl ether, methyl phenyl ether, ethyl phenyl ether, diphenyl ether, dialkoxy benzene, trialkoxy benzene, N,N-dimethylacetamide (DMAc), N,N-dimethylformamide (DMF), N-methyl-2-pyrrolidone (NMP), 1,3-dimethyl-2-imidazolidinone, 7-butyrolactone, sulfolane, dimethyl sulfoxide, diethyl sulfoxide, dimethyl sulfone, diethyl sulfone, diisopropyl sulfone, diphenyl sulfone, benzophenone, 2-heptanone, cyclohexanone, methyl ethyl ketone, dichloromethane, chloroform, chlorobenzene, benzene, toluene, and xylene. The aforementioned organic solvents can be used individually or in a mixture of two or more.

Examples of the alkali metal or alkali metal compound include, but are not limited to, lithium, sodium, potassium, sodium hydride, potassium hydride, lithium hydride, lithium carbonate, sodium carbonate, potassium carbonate, lithium hydrogen carbonate, sodium hydrogen carbonate, and potassium hydrogen carbonate. The aforementioned alkali metals or alkali metal compounds can be used individually or in a mixture of two or more.

The amount of the thermosetting nitrogen-containing heterocyclic copolymer can be adjusted depending on the need. Generally, based on the total weight of the resin composition, the amount of the thermosetting nitrogen-containing heterocyclic copolymer can be 15 wt % to 60 wt %. For example, based on the total weight of the resin composition, the amount of the thermosetting nitrogen-containing heterocyclic copolymer can be 15 wt %, 20 wt %, 25 wt %, 30 wt %, 35 wt %, 40 wt %, 45 wt %, 50 wt %, 55 wt %, or 60 wt %, or within a range between any two of the values described herein.

### 1.2.2.2. Optional Additive

Examples of additives applicable in the dielectric materials include, but are not limited to, a hardener, a catalyst, an elastomer, a filler, a dispersing agent, a toughener, a viscosity modifying agent, a flame retardant, and a coupling agent. The aforementioned additives can be used individually or in a mixture of two or more.

### [Hardener]

As used herein, a hardener refers to a component that can undergo crosslinking reaction with other components (e.g., an epoxy resin, or a thermosetting polyphenylene ether resin) to form a stereo network structure. The types of the hardener are not particularly limited as long as it can increase the degree of crosslinking. Examples of the hardener include, but are not limited to, a cyanate ester resin, a BZ resin, phenolic resin (PN resin), styrene maleic anhydride copolymer (SMA copolymer), bismaleimide (BMI), dicyandiamide (Dicy), 4,4′-diaminodiphenyl sulfone (DDS), 1,3-divinylbenzene, 1,4-divinylbenzene, trivinylbenzene, 1,3-diisopropenylbenzene, 1,4-diisopropenylbenzene, and a vinyl and/or allyl-containing isocyanurate. The aforementioned hardeners can be used individually or in a mixture of two or more. In the appended examples, allyl-containing isocyanurate is used.

The amount of the hardener can be adjusted depending on the need. Generally, based on the total weight of the resin composition, the amount of the hardener can range from 15 wt % to 60 wt %. For example, based on the total weight of the resin composition, the amount of the hardener can be 15 wt %, 20 wt %, 25 wt %, 30 wt %, 35 wt %, 40 wt %, 45 wt %, 50 wt %, 55 wt %, or 60 wt %, or within a range between any two of the values described herein.

### [Catalyst]

As used herein, a catalyst refers to a component that can promote a curing reaction, for example, a component that can promote the ring-opening reaction of epoxy functional groups and lower the crosslinking reaction temperature of the resin composition. The type of the catalyst is not particularly limited as long as it can promote a crosslinking reaction. Suitable catalysts include, but are not limited to, organic peroxides, tertiary amines, quaternary ammonium salts, imidazole compounds, and pyridine compounds. Examples of the organic peroxide include, but are not limited to, dicumyl peroxide (DCP), tert-butylperoxybenzoate, di-tert-amylperoxide, isopropyl cumyl-t-butyl peroxide, tert-butylcumyl peroxide, di(isopropylcumyl)peroxide, di-tert-butyl peroxide, α,α′-bis(t-butylperoxy)diisopropyl benzene, dibenzoyl peroxide, 1,1-bis(tert-butylperoxy)-3,3,5-trimethylcyclohexane, n-butyl-4,4-bis(tert-butylperoxy)valerate, 2,5-dimethyl-2,5-di-(tert-butylperoxy)hexane, and 2,5-dimethyl-2,5-di(tert-butylperoxy)-3-hexyne. The aforementioned organic peroxides can be used individually or in a mixture of two or more. In the appended examples, α,α′-bis(t-butylperoxy)diisopropyl benzene is used.

The amount of the catalyst can be adjusted depending on the need. Generally, based on the total weight of the resin composition, the amount of the catalyst can range from 0.1 wt % to 1 wt %. For example, based on the total weight of the resin composition, the amount of the catalyst can be 0.1 wt %, 0.2 wt %, 0.3 wt %, 0.4 wt %, 0.5 wt %, 0.6 wt %, 0.7 wt %, 0.8 wt %, 0.9 wt %, or 1 wt %, or within a range between any two of the values described herein.

### [Elastomer]

As used herein, an elastomer refers to a polymer with viscoelasticity that can impart toughness to electronic materials. Examples of the elastomer include, but are not limited to, polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, and functional-modified derivatives thereof. The aforementioned elastomers can be used individually or in a mixture of two or more. Examples of the functional-modified derivatives include, but are not limited to, maleic anhydride-modified polybutadiene, and maleic anhydride-modified polybutadiene-styrene copolymer. In the appended examples, a styrene-butadiene copolymer or a styrene-butadiene-divinylbenzene copolymer is used.

The amount of the elastomer can be adjusted depending on the need. Generally, based on the total weight of the resin composition, the amount of the elastomer can range from 1 wt % to 10 wt %. For example, based on the total weight of the resin composition, the amount of the elastomer can be 1 wt %, 2 wt %, 3 wt %, 4 wt %, 5 wt %, 6 wt %, 7 wt %, 8 wt %, 9 wt %, or 10 wt %, or within a range between any two of the values described herein.

[Flame Retardant]

The resin composition can optionally further comprise a flame retardant to improve the thermal resistance and flame retardance of the prepared electronic materials. The types of the flame retardant include, but are not limited to, a phosphorus-containing flame retardant, a bromine-containing flame retardant and a nitrogen-containing compound. These flame retardants can be used individually or in a mixture of two or more.

Examples of the phosphorus-containing flame retardant include, but are not limited to, phosphate esters, phosphazenes, ammonium polyphosphate, metal phosphinates, and melamine phosphate. The aforementioned phosphorus-containing flame retardants can be used individually or in a mixture of two or more.

Examples of the bromine-containing flame retardant include, but are not limited to, tetrabromobisphenol A, decabromodiphenyloxide, decabrominated diphenyl ethane, 1,2-bis(tribromophenyl) ethane, brominated epoxy oligomer, octabromotrimethylphenyl indane, bis(2,3-dibromopropyl ether), tris(tribromophenyl) triazine, brominated aliphatic hydrocarbon, and brominated aromatic hydrocarbon. The aforementioned bromine-containing flame retardants can be used individually or in a mixture of two or more. Examples of the nitrogen-containing compound include, but are not limited to, melamine and derivatives thereof. The commercially available phosphorus-containing flame retardants include product Melapur 200 available from BASF Company.

The amount of the flame retardant can be adjusted depending on the need and is not particularly limited. Generally, based on the total weight of the resin composition, the amount of the flame retardant can range from 0 wt % to 30 wt %. For example, based on the total weight of the resin composition, the amount of the flame retardant can be 0 wt %, 1 wt %, 5 wt %, 10 wt %, 15 wt %, 20 wt %, 25 wt %, or 30 wt %, or within a range between any two of the values described herein.

### [Filler]

The resin composition can optionally further comprise a filler improve the mechanical strength, thermal conductivity and dimensional stability of the prepared electronic materials. Examples of suitable fillers include, but are not limited to, those selected from the group consisting of silicon dioxide (including hollow silicon dioxide), alumina, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond powder, diamond-like powder, graphite, calcined kaolin, pryan, mica, hydrotalcite, polytetrafluoroethylene (PTFE) powder, glass bead, ceramic whisker, carbon nanotube, and nanosized inorganic powder. The aforementioned fillers can be used individually or in a mixture of two or more. In the appended examples, the filler is silica.

The amount of the filler can be adjusted depending on the need and is not particularly limited. Generally, based on the total weight of the resin composition, the amount of the filler can be 0 wt % to 60 wt %. For example, based on the total weight of the resin composition, the amount of the filler can be 0 wt %, 1 wt %, 5 wt %, 10 wt %, 15 wt %, 20 wt %, 25 wt %, 30 wt %, 35 wt %, 40 wt %, 45 wt %, 50 wt %, 55 wt %, or 60 wt %, or within a range between any two of the values described herein.

[Preparation of Resin Composition]

The resin composition may be prepared into a slurry, a colloidal group, a varnish, or other forms for subsequent processing by uniformly mixing the components of the resin composition, including the thermosetting resin and optional additives, with a stirrer, and dissolving or dispersing the resultant mixture in a solvent. The solvent can be any inert solvent that can dissolve or disperse the components of the resin composition but does not react with those components. Examples of the solvent that can dissolve or disperse the components of the resin composition include, but are not limited to, toluene, 7-butyrolactone, methyl ethyl ketone, cyclohexanone, butanone, acetone, xylene, methyl isobutyl ketone, DMF, DMAc, and NMP. The aforementioned solvents can be used individually or in a mixture of two or more. The amount of the solvent in the resin composition is not particularly limited as long as the components of the resin composition can be evenly dissolved or dispersed therein. In the appended examples, methyl ethyl ketone and toluene are used.

### 1.3. Preparation of Copper Clad Laminate

The copper clad laminate of the present invention can be prepared as follows. First, a resin sheet prepared using the method described earlier is provided as a dielectric layer. Subsequently, a copper foil with the aforementioned properties is provided and disposed on at least one side of the dielectric layer to obtain a superimposed object. The superimposed object is subjected to a hot-pressing operation to obtain a copper clad laminate. The hot-pressing is performed at a temperature of 180° C. to 230° C. and a full pressure of 10 kg/cm² to 25 kg/cm² (with an initial pressure of 5 kg/cm² to 12 kg/cm²) for a duration of 1 (one) hour to 4 hours.

### 2. Printed Circuit Board

The copper clad laminate of the present invention can form a printed circuit board by further patterning its outer copper foil. Therefore, the present invention also provides a printed circuit board, which is manufactured by further patterning the outer copper foil of the copper clad laminate of the present invention. The method for patterning the copper foil is not particularly limited. For example, the patterning method includes photolithography.

### 3. Examples

### 3.1. Testing Methods

### [Measurement of Element Content at Surface]

First, the copper foil is cut into 10 cm×10 cm test samples, and transparent tape is used to cover the non-measurement side (i.e., the second surface, not the first surface). Next, the test sample is laid flat in a glass container with the first surface facing up. A 100 ml of nitric acid solution with a weight percent concentration of 21% (composition: nitric acid and water) is poured into the glass container, ensuring the liquid level covers the test sample. After soaking at room temperature for 30 seconds, the test sample is removed and analyzed using ICP (inductively coupled plasma) emission spectrometry to measure the content of zinc, nickel and chromium in the nitric acid solution. The same test is conducted on three test samples, and the average value is taken to determine the content of zinc, nickel, and chromium at the surface of the copper foil. The unit for element content is μg/dm².

### [Measurement of Ten-Point Average Roughness (Rz)]

The ten-point average roughness (Rz) of the copper foil is measured in accordance with JIS B0601:2001. The unit of Rz is μm.

### [Peeling Strength Test]

The peeling strength refers to the adhesion between the copper foil and the dielectric layer. The peeling strength is expressed by the force required for vertically peeling off a ⅛-inch-wide copper foil from the laminate. The unit for the peeling strength is lbf/in.

### [Chemical Resistance Test]

The initial peeling strength of the copper clad laminate is measured in advance according to the method described in the previous section “Peeling strength test”. Then, the copper clad laminate is cut into 10 cm×10 cm test samples, and the test samples are etched to obtain patterned test samples with line widths of 1 mm/3 mm. The patterned test samples are then placed with the patterned side facing up in a glass container, and 100 ml of an 18 wt % hydrochloric acid solution (composition: hydrochloric acid and water) is poured into the glass container, ensuring the liquid level covers the patterned test samples. After soaking at room temperature for 1 (one) hour, the patterned test samples are removed, and the peeling strength of the patterned test samples after treatment is measured according to the method described in the previous section “Peeling strength test”. The unit for the peeling strength is lbf/in. The declining rate of peeling strength of the copper clad laminate is calculated based on the initial peeling strength and the post-treatment peeling strength, and evaluated according to the following criteria.

$$Declining rate of peeling strength = \frac{( Initial peeling strength - Post - treatment peeling strength )}{Initial peeling strength} \times 100 \%$$

Declining rate of peeling strength is 5% or less
Declining rate of peeling strength is greater than 5% and no more than 10%
Declining rate of peeling strength is greater than 10%

### [Infrared Reflow Resistance Test]

The infrared reflow resistance is represented by the peeling strength of the copper clad laminate after infrared reflow treatment. First, the copper clad laminate is placed in an infrared reflow oven (model: TSK-8000, available from Der Pan Electric Mechanical Industrial) to reflow at 260° C. for 10 seconds, which constitutes one reflow cycle. After performing six reflow cycles, the peeling strength of the copper clad laminate after infrared reflow treatment is measured according to the method described in the previous section “Peeling strength test”. The peeling strength is then evaluated according to the following criteria, where a higher peeling strength indicates better infrared reflow resistance. The unit for the peeling strength is lbf/in.
Peeling strength is 3.00 lbf/in or more
Peeling strength is 2.70 lbf/in or more and less than 3.00 lbf/in
Peeling strength is 2.50 lbf/in or more and less than 2.70 lbf/in
Peeling strength is less than 2.50 lbf/in

### [Signal Integrity Test]

The signal integrity of the copper clad laminate is tested at 16 GHz according to the Delta-L testing method of Intel Corporation. The test items of signal integrity include 3 mils Core (one ounce), 10 mils PP and 4.5 mils Trace Width. The unit for the signal integrity is dB/in (decibels per inch). The closer the signal integrity value is to zero, the better the signal integrity. Generally, it is well known in the industry that a difference in signal integrity of 2% or more is considered a significantly difference, a difference in signal integrity of 3% or more is considered a very significantly difference, and a difference in signal integrity of 5% or more represents a generational difference in product performance. For example, a product generation difference can be seen between Intel's Whitley platform and Eagle stream platform. For instance, if product A has a signal integrity of 0.4 dB/in and product B has a signal integrity of 0.5 dB/in, the difference (an absolute value) between the two products would be calculated as [(0.5−0.4)/0.4]×100%=25%.

### 3.2. List of Raw Materials Used in Examples and Comparative Examples

TABLE 2
List of raw materials

| Model no. | Description |
|---|---|
| TAIC | Triallyl isocyanurate, a hardener, available from Evonik |
| | Industries |
| SA9000 | Polyphenylene ether, available from SABIC |
| Ricon 100 | Elastomer, butadiene-styrene copolymer, available from Cray |
| | Valley |
| Ricon 257 | Elastomer, butadiene-styrene-divinylbenzene copolymer, |
| | available from Cray Valley |
| Perbutyl P | Catalyst, α,α′-bis(t-butylperoxy)diisopropyl benzene, |
| | available from NOF |
| SC-5500 | SiO₂ filler, available from Admatech |
| SVC | |

### 3.3. Preparation of Copper Clad Laminate

### [Preparation Example 1 for Dielectric Layer]

50.0 g of polyphenylene ether SA9000, 50.0 g of TAIC, 10.0 g of elastomer Ricon 100, 1.0 g of catalyst Perbutyl P and 100.0 g of filler SC-5500 SVC were mixed using a stirrer at room temperature. Methyl ethyl ketone (available from Methyl Company) and toluene (available from Trans Chief Chemical Industry Company) were then added to the mixture. Subsequently, the resultant mixture was stirred at room temperature for 60 to 120 minutes to obtain a polyphenylene ether resin composition. Afterwards, a 1080 type E-glass fiber fabric (thickness: 64 m) was impregnated with the polyphenylene ether resin composition. The impregnated E-glass fiber fabric was then baked at 360° C. for 2 minutes, thereby obtaining a PPE dielectric layer with a reinforcing material (hereinafter the “PPE dielectric layer”). The thickness of the PPE dielectric layer is 254 μm.

### [Preparation Example 2 for Dielectric Layer]

In an inert atmosphere, 29 g of 2,2-bis(4-hydroxy-3-methylphenyl)propane, 18.9 g of 2-phenyl-4,6-dichloropyrimidine, and 21.2 g of potassium carbonate were added into a 500 mL round-bottom flask, followed by the addition of 46.7 g of N-methyl-2-pyrrolidone as the solvent. The obtained mixture was then stirred and reacted at 100° C. for 6 hours. After the reaction is complete, the resultant intermediate product was cooled to 10° C., and at 10° C., 12.7 g of a mixture of 3-(chloromethyl)styrene and 4-(chloromethyl)styrene was slowly titrated into the round-bottom flask. The intermediate product was then increased to 100° C., and the reaction was allowed to continue for 4 hours at 100° C. Afterward, 61 g of N-methyl-2-pyrrolidone was added into the round-bottom flask and stirred for 30 minutes. Methanol was then added to repeatedly wash and filter the resultant product, and solvent was removed by rotary evaporation to obtain a nitrogen-containing heterocyclic copolymer represented by the following formula (I). In formula (I), n is an integer of 1 (one) to 5.

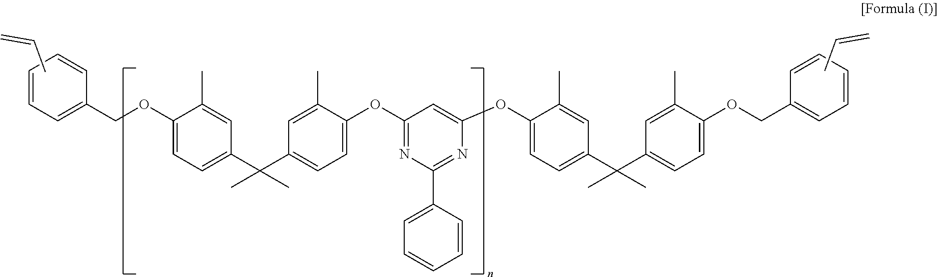

50.0 g of the nitrogen-containing heterocyclic copolymer represented by formula (I), 50.0 g of TAIC, 10.0 g of elastomer Ricon 257, 1.0 g of catalyst Perbutyl P, and 100.0 g of filler SC-5500 SVC were mixed using a stirrer at room temperature. Methyl ethyl ketone and toluene were then added to the mixture. Subsequently, the resultant mixture was stirred at room temperature for 60 to 120 minutes to obtain a nitrogen-containing heterocyclic copolymer composition. Afterwards, a 1080 type E-glass fiber fabric (thickness: 64 m) was impregnated with the nitrogen-containing heterocyclic copolymer composition. The impregnated E-glass fiber fabric was then baked at 175° C. for 2 minutes to 5 minutes, thereby obtaining a nitrogen-containing heterocyclic copolymer dielectric layer with a reinforcing material (hereinafter the “nitrogen-containing heterocyclic copolymer dielectric layer”). The thickness of the nitrogen-containing heterocyclic copolymer dielectric layer is 254 m.

### [Preparation Example for Copper Foil]

First, a copper electrolyte solution comprising copper ions (Cu²⁺) at concentrations from 65 g/L to 100 g/L, sulfuric acid (H₂SO₄) at concentrations from 85 g/L to 105 g/L and chloride ions (Cl⁻) between 1.0 ppm to 30 ppm was prepared. Subsequently, the copper electrolyte solution was introduced into a raw foil electrolysis equipment equipped with a rotating cathode roll and an insoluble anode. A current with a current density ranging from 30 A/dm² to 60 A/dm² was applied to the cathode roll and the insoluble anode, respectively. Afterwards, the copper electrolyte solution was maintained at a temperature of 50° C. to 58° C., and a raw foil is obtained and continuously wound onto a guiding roll.

Next, the raw foil was conveyed into a continuous surface treatment device at a transport speed of 16 m/min via multiple guiding rolls. It underwent surface treatments as specified in Tables 3-1, 3-2, 3-3, 3-4, 3-5, 3-6 and 3-7 to produce Copper foil 1 to Copper foil 34. The Rz, zinc content, nickel content, and chromium content at the first surface of Copper foil 1 to Copper foil 34 were measured using the aforementioned testing methods, and the results are tabulated in Tables 3-1, 3-2, 3-3, 3-4, 3-5, 3-6 and 3-7.

TABLE 3-1
Treatment conditions and properties of Copper foil 1 to Copper foil 5

| | | | Copper | Copper | Copper | Copper | Copper |
|---|---|---|---|---|---|---|---|
| Treatment time and conditions | | | foil 1 | foil 2 | foil 3 | foil 4 | foil 5 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 3.7 | 3.7 | 3.7 | 3.7 | 3.7 |
| | 9 | Current (ampers) | 16.5 | 16.5 | 16.5 | 4.4 | 4.4 |
| | 10 | Immersion solution | Pure | Chromic | Chromic | Pure | Chromic |
| | | | water | acid and | acid and | water | acid and |
| | | | | phosphoric | phosphoric | | phosphoric |
| | | | | acid | acid | | acid |
| | | Immersion time | 1 | 1 | 1 | 1 | 1 |
| | | (seconds) | | | | | |
| | 10A | Water rinsing time | 3 | 6 | 5 | 3 | 6 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 30 | 30 | 30 | 30 | 30 |
| | Zinc content (μg/dm²) | 150 | 150 | 150 | 40 | 40 |
| | Chromium content (μg/dm²) | 0 | 0.5 | 1 | 0 | 0.5 |

TABLE 3-2
Treatment conditions and properties of Copper foil 6 to Copper foil 10

| | | | Copper | Copper | Copper | Copper | Copper |
|---|---|---|---|---|---|---|---|
| Treatment time and conditions | | | foil 6 | foil 7 | foil 8 | foil 9 | foil 10 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 3.7 | 3.7 | 3.7 | 3.7 | 1.2 |
| | 9 | Current (ampers) | 4.4 | 49.6 | 49.6 | 49.6 | 4.4 |
| | 10 | Immersion solution | Chromic | Pure | Chromic | Chromic | Pure |
| | | | acid and | water | acid and | acid and | water |
| | | | phosphoric | | phosphoric | phosphoric | |
| | | | acid | | acid | acid | |
| | | Immersion time | 1 | 1 | 1 | 1 | 1 |
| | | (seconds) | | | | | |
| | 10A | Water rinsing time | 5 | 3 | 6 | 5 | 3 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 30 | 30 | 30 | 30 | 10 |
| | Zinc content (μg/dm²) | 40 | 450 | 450 | 450 | 40 |
| | Chromium content (μg/dm²) | 1 | 0 | 0.5 | 1 | 0 |

TABLE 3-3
Treatment conditions and properties of Copper foil 11 to Copper foil 15

| | | | Copper | Copper | Copper | Copper | Copper |
|---|---|---|---|---|---|---|---|
| Treatment time and conditions | | | foil 11 | foil 12 | foil 13 | foil 14 | foil 15 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 1.2 | 1.2 | 1.2 | 1.2 | 1.2 |
| | 9 | Current (ampers) | 4.4 | 4.4 | 49.6 | 49.6 | 49.6 |
| | 10 | Immersion solution | Chromic | Chromic | Pure | Chromic | Chromic |
| | | | acid and | acid and | water | acid and | acid and |
| | | | phosphoric | phosphoric | | phosphoric | phosphoric |
| | | | acid | acid | | acid | acid |
| | | Immersion time | 1 | 1 | 1 | 1 | 1 |
| | | (seconds) | | | | | |
| | 10A | Water rinsing time | 6 | 5 | 3 | 6 | 5 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 10 | 10 | 10 | 10 | 10 |
| | Zinc content (μg/dm²) | 40 | 40 | 450 | 450 | 450 |
| | Chromium content (μg/dm²) | 0.5 | 1 | 0 | 0.5 | 1 |

TABLE 3-4
Treatment conditions and properties of Copper foil 16 to Copper foil 20

| | | | Copper | Copper | Copper | Copper | Copper |
|---|---|---|---|---|---|---|---|
| Treatment time and conditions | | | foil 16 | foil 17 | foil 18 | foil 19 | foil 20 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 2.5 | 2.5 | 2.5 | 3.7 | 3.7 |
| | 9 | Current (ampers) | 16.5 | 16.5 | 16.5 | 55.1 | 55.1 |
| | 10 | Immersion solution | Pure | Chromic | Chromic | Pure | Chromic |
| | | | water | acid and | acid and | water | acid and |
| | | | | phosphoric | phosphoric | | phosphoric |
| | | | | acid | acid | | acid |
| | | Immersion time | 1 | 1 | 1 | 1 | 1 |
| | | (seconds) | | | | | |
| | 10A | Water rinsing time | 3 | 6 | 5 | 3 | 6 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 20 | 20 | 20 | 30 | 30 |
| | Zinc content (μg/dm²) | 150 | 150 | 150 | 500 | 500 |
| | Chromium content (μg/dm²) | 0 | 0.5 | 1 | 0 | 0.5 |

TABLE 3-5
Treatment conditions and properties of Copper foil 21 to Copper foil 25

| | | | Copper | Copper | Copper | Copper | Copper |
|---|---|---|---|---|---|---|---|
| Treatment time and conditions | | | foil 21 | foil 22 | foil 23 | foil 24 | foil 25 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 3.7 | 1.0 | 1.0 | 1.0 | 6.1 |
| | 9 | Current (ampers) | 55.1 | 4.4 | 4.4 | 4.4 | 4.4 |
| | 10 | Immersion solution | Chromic | Pure | Chromic | Chromic | Pure |
| | | | acid and | water | acid and | acid and | water |
| | | | phosphoric | | phosphoric | phosphoric | |
| | | | acid | | acid | acid | |
| | | Immersion time | 1 | 1 | 1 | 1 | 1 |
| | | (seconds) | | | | | |
| | 10A | Water rinsing time | 5 | 3 | 6 | 5 | 3 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 30 | 8 | 8 | 8 | 50 |
| | Zinc content (μg/dm²) | 500 | 450 | 450 | 450 | 40 |
| | Chromium content (μg/dm²) | 1 | 0 | 0.5 | 1 | 0 |

TABLE 3-6
Treatment conditions and properties of Copper foil 26 to Copper foil 30

| | | | Copper | Copper | Copper | Copper | Copper |
|---|---|---|---|---|---|---|---|
| Treatment time and conditions | | | foil 26 | foil 27 | foil 28 | foil 29 | foil 30 |
| Treatment | 1 | Current (ampers) | 1450 | 1450 | 1450 | 1450 | 1450 |
| tank | 1A | Current (ampers) | 0 | 0 | 0 | 0 | 0 |
| | 2 | Current (ampers) | 100 | 100 | 100 | 100 | 100 |
| | 3 | Current (ampers) | 0 | 0 | 0 | 0 | 0 |
| | 4 | Current (ampers) | 310 | 310 | 310 | 310 | 310 |
| | 5 | Current (ampers) | 280 | 280 | 280 | 280 | 280 |
| | 6 | Current (ampers) | 20 | 20 | 20 | 20 | 20 |
| | 7 | Current (ampers) | 20 | 20 | 20 | 20 | 20 |
| | 8 | Current (ampers) | 6.1 | 6.1 | 6.1 | 6.1 | 6.1 |
| | 9 | Current (ampers) | 4.4 | 4.4 | 49.6 | 49.6 | 49.6 |
| | 10 | Immersion solution | Chromic | Chromic | Pure | Chromic | Chromic |
| | | | acid and | acid and | water | acid and | acid and |
| | | | phosphoric | phosphoric | | phosphoric | phosphoric |
| | | | acid | acid | | acid | acid |
| | | Immersion time | 1 | 1 | 1 | 1 | 1 |
| | | (seconds) | | | | | |
| | 10A | Water rinsing time | 6 | 5 | 3 | 6 | 5 |
| | | (seconds) | | | | | |
| | | Water flow rate (L/s) | 1.0 | 1.0 | 1.0 | 1.0 | 1.0 |
| | 11 | Immersion time | 2 | 2 | 2 | 2 | 2 |
| | | (seconds) | | | | | |

| | | | | | | |
|---|---|---|---|---|---|---|
| Properties | Rz (μm) | 0.336 | 0.336 | 0.336 | 0.336 | 0.336 |
| | Nickel content (μg/dm²) | 50 | 50 | 50 | 50 | 50 |
| | Zinc content (μg/dm²) | 40 | 40 | 450 | 450 | 450 |
| | Chromium content (μg/dm²) | 0.5 | 1 | 0 | 0.5 | 1 |

TABLE 3-7
Treatment conditions and properties of Copper foil 31 to Copper foil 34

| | | | Copper | Copper | Copper | Copper |
|---|---|---|---|---|---|---|
| Treatment time and conditions | | | foil 31 | foil 32 | foil 33 | foil 34 |
| Treatment | 1 | Current (ampers) | 1450 | 1450 | 1450 | 1450 |
| tank | 1A | Current (ampers) | 0 | 0 | 0 | 0 |
| | 2 | Current (ampers) | 100 | 100 | 100 | 100 |
| | 3 | Current (ampers) | 0 | 0 | 0 | 0 |
| | 4 | Current (ampers) | 310 | 310 | 310 | 310 |
| | 5 | Current (ampers) | 280 | 280 | 280 | 280 |
| | 6 | Current (ampers) | 20 | 20 | 20 | 20 |
| | 7 | Current (ampers) | 20 | 20 | 20 | 20 |
| | 8 | Current (ampers) | 3.7 | 3.7 | 3.7 | 3.7 |
| | 9 | Current (ampers) | 2.2 | 2.2 | 16.5 | 16.5 |
| | 10 | Immersion solution | Chromic | Chromic | Chromic | Chromic |
| | | | acid and | acid and | acid and | acid and |
| | | | phosphoric | phosphoric | phosphoric | phosphoric |
| | | | acid | acid | acid | acid |
| | | Immersion time | 1 | 1 | 1 | 1 |
| | | (seconds) | | | | |
| | 10A | Water rinsing time | 6 | 5 | 3 | 1 |
| | | (seconds) | | | | |
| | | Water flow rate (L/s) | 1.0 | 1.0 | 1.0 | 1.0 |
| | 11 | Immersion time | 2 | 2 | 2 | 2 |
| | | (seconds) | | | | |

| | | | | | |
|---|---|---|---|---|---|
| Properties | Rz (μm) | 0.336 | 0.336 | 0.336 | 0.336 |
| | Nickel content (μg/dm²) | 30 | 30 | 30 | 30 |
| | Zinc content (μg/dm²) | 20 | 20 | 150 | 150 |
| | Chromium content (μg/dm²) | 0.5 | 1 | 2 | 5 |

### [Preparation of Copper Clad Laminate]

Copper clad laminates of Examples 1 to 21 and Comparative Examples 1 to 16 were individually prepared according to the compositions as recited in Table 4 using the following methods. First, multiple pieces of the dielectric layer were superimposed, and two sheets of copper foils (each 0.5 oz.) were applied to the respective outermost layers. Subsequently, the assembled materials were placed in a hot press machine to undergo a high temperature hot-pressing. The hot-pressing conditions were as follows: heating to 200° C. to 220° C. at a heating rate of 2° C./min to 4° C./min, followed by hot-pressing at 200° C. to 220° C. for 120 minutes under a full pressure of 18 kg/cm² (with an initial pressure of 8 kg/cm²). The properties of the copper clad laminates of Examples 1 to 21 and Comparative Examples 1 to 16, including peeling strength, chemical resistance, infrared reflow resistance and signal integrity, were tested according to the aforementioned testing methods. The results are tabulated in Tables 5-1 and 5-2.

TABLE 4
Compositions of copper clad laminates
of Examples and Comparative Examples

| | Copper foil | Dielectric layer |
|---|---|---|
| Example 1 | Copper foil 1 | PPE |
| Example 2 | Copper foil 2 | dielectric layer |
| Example 3 | Copper foil 3 | |
| Example 4 | Copper foil 4 | |
| Example 5 | Copper foil 5 | |
| Example 6 | Copper foil 6 | |
| Example 7 | Copper foil 7 | |
| Example 8 | Copper foil 8 | |
| Example 9 | Copper foil 9 | |
| Example 10 | Copper foil 10 | |
| Example 11 | Copper foil 11 | |
| Example 12 | Copper foil 12 | |
| Example 13 | Copper foil 13 | |
| Example 14 | Copper foil 14 | |
| Example 15 | Copper foil 15 | |
| Example 16 | Copper foil 16 | |
| Example 17 | Copper foil 17 | |
| Example 18 | Copper foil 18 | |
| Example 19 | Copper foil 16 | Nitrogen- |
| Example 20 | Copper foil 17 | containing |
| Example 21 | Copper foil 18 | heterocyclic |
| | | copolymer |
| | | dielectric layer |
| Comparative Example 1 | Copper foil 19 | PPE |
| Comparative Example 2 | Copper foil 20 | dielectric layer |
| Comparative Example 3 | Copper foil 21 | |
| Comparative Example 4 | Copper foil 22 | |
| Comparative Example 5 | Copper foil 23 | |
| Comparative Example 6 | Copper foil 24 | |
| Comparative Example 7 | Copper foil 25 | |
| Comparative Example 8 | Copper foil 26 | |
| Comparative Example 9 | Copper foil 27 | |
| Comparative Example 10 | Copper foil 28 | |
| Comparative Example 11 | Copper foil 29 | |
| Comparative Example 12 | Copper foil 30 | |
| Comparative Example 13 | Copper foil 31 | |
| Comparative Example 14 | Copper foil 32 | |
| Comparative Example 15 | Copper foil 33 | |
| Comparative Example 16 | Copper foil 34 | |

TABLE 5-1
Properties of copper clad laminates of Examples 1 to 21

| | Peeling | | | Signal |
|---|---|---|---|---|
| | strength | Chemical | Infrared reflow | integrity |
| | (lbf/in) | resistance | resistance | (dB/in) |
| Example 1 | 3.84 | ∘∘ | ∘∘ | −0.48626 |
| Example 2 | 3.83 | ∘∘ | ∘∘ | −0.48016 |
| Example 3 | 3.83 | ∘∘ | ∘∘ | −0.48928 |
| Example 4 | 3.51 | ∘∘ | ∘∘ | −0.48405 |
| Example 5 | 3.51 | ∘∘ | ∘∘ | −0.47880 |
| Example 6 | 3.50 | ∘∘ | ∘∘ | −0.48632 |
| Example 7 | 3.91 | ∘ | ∘∘ | −0.49930 |
| Example 8 | 3.93 | ∘ | ∘∘ | −0.49371 |
| Example 9 | 3.97 | ∘ | ∘∘ | −0.50060 |
| Example 10 | 3.61 | ∘∘ | ∘∘ | −0.46989 |
| Example 11 | 3.57 | ∘∘ | ∘∘ | −0.46248 |
| Example 12 | 3.57 | ∘∘ | ∘∘ | −0.47077 |
| Example 13 | 3.93 | ∘ | ∘∘ | −0.47433 |
| Example 14 | 3.94 | ∘ | ∘∘ | −0.47109 |
| Example 15 | 3.95 | ∘ | ∘∘ | −0.48125 |
| Example 16 | 3.88 | ∘∘ | ∘∘ | −0.47433 |
| Example 17 | 3.88 | ∘∘ | ∘∘ | −0.47327 |
| Example 18 | 3.92 | ∘∘ | ∘∘ | −0.49374 |
| Example 19 | 3.75 | ∘∘ | ∘∘ | −0.46340 |
| Example 20 | 3.80 | ∘∘ | ∘∘ | −0.45622 |
| Example 21 | 3.87 | ∘∘ | ∘∘ | −0.46722 |

TABLE 5-2
Properties of copper clad laminates
of Comparative Examples 1 to 16

| | Peeling | | Infrared | Signal |
|---|---|---|---|---|
| | strength | Chemical | reflow | integrity |
| | (lbf/in) | resistance | resistance | (dB/in) |
| Comparative Example 1 | 4.13 | x | ∘∘ | −0.51260 |
| Comparative Example 2 | 4.09 | x | ∘∘ | −0.51535 |
| Comparative Example 3 | 3.98 | x | ∘∘ | −0.52388 |
| Comparative Example 4 | 2.60 | ∘∘ | x | −0.46038 |
| Comparative Example 5 | 2.60 | ∘∘ | x | −0.46034 |
| Comparative Example 6 | 2.60 | ∘∘ | x | −0.46351 |
| Comparative Example 7 | 2.40 | ∘∘ | Δ | −0.51329 |
| Comparative Example 8 | 2.42 | ∘∘ | Δ | −0.51062 |
| Comparative Example 9 | 2.45 | ∘∘ | Δ | −0.51397 |
| Comparative Example 10 | 3.40 | ∘∘ | ∘∘ | −0.53127 |
| Comparative Example 11 | 3.45 | ∘∘ | ∘∘ | −0.52559 |
| Comparative Example 12 | 3.45 | ∘∘ | ∘∘ | −0.52759 |
| Comparative Example 13 | 2.53 | ∘∘ | x | −0.51835 |
| Comparative Example 14 | 2.54 | ∘∘ | x | −0.52055 |
| Comparative Example 15 | 3.82 | ∘∘ | ∘∘ | −0.51527 |
| Comparative Example 16 | 3.84 | ∘∘ | ∘∘ | −0.53733 |

As shown in Table 5-1, the copper clad laminates of the present invention exhibit good peeling strength, good chemical resistance, good infrared reflow resistance, and good signal integrity. Specifically, under the condition of using the same dielectric layer, the copper clad laminate can simultaneously achieve good peeling strength, good chemical resistance, good infrared reflow resistance, and good signal integrity only when the zinc, nickel, and chromium contents at the first surface of the copper foil are all within the specified ranges. The favorable properties achieved by the copper clad laminate of the present invention cannot be improved by the content of a single metal element alone; rather, they require the synergistic effect of zinc, nickel, and chromium to be improved. More specifically, when the zinc, nickel, and chromium contents at the first surface of the copper foil are all within the preferred ranges, the resulting copper clad laminate exhibits further improvement in peeling strength, chemical resistance, infrared reflow resistance, and signal integrity.

By contrast, as shown in Table 5-2, the copper clad laminates outside the scope of the present invention cannot simultaneously exhibit good peeling strength, chemical resistance, infrared reflow resistance, and signal integrity. Specifically, under the condition of using the same dielectric layer, if any one of the zinc, nickel, and chromium contents at the first surface of the copper foil falls outside the specified range, the resulting copper clad laminate will not simultaneously achieve good peeling strength, chemical resistance, infrared reflow resistance, good signal integrity. For example, Comparative Examples 1 to 3 show that when the zinc content at the first surface of the copper foil exceeds the specified range, the resulting copper clad laminate exhibits poor chemical resistance and signal integrity. Comparative Examples 13 and 14 show that when the zinc content at the first surface of the copper foil is below the specified range, the resulting copper clad laminate has poor peeling strength, infrared reflow resistance and signal integrity. Comparative Examples 4 to 6 show that when the nickel content at the first surface of the copper foil is below the specified range, the resulting copper clad laminate exhibits poor peeling strength and infrared reflow resistance. Comparative Examples 7 to 12 show that when the nickel content at the first surface of the copper foil exceeds the specified range, the resulting copper clad laminate has poor peeling strength and signal integrity, and may also have poor infrared reflow resistance. Comparative Examples 15 and 16 show that when the chromium content at the first surface of the copper foil exceeds the specified range, the resulting copper clad laminate exhibits poor signal integrity.

The above examples are used to illustrate the principle and efficacy of the present invention and show the inventive features thereof, but are not used to limit the scope of the present invention. People skilled in this field may proceed with a variety of modifications and replacements based on the disclosures and suggestions of the invention as described. Therefore, the scope of protection of the present invention is that as defined in the claims as appended.

What is claimed is:

1. A copper-clad laminate, comprising:
a dielectric layer; and
at least one copper foil which has a first surface,
wherein the copper foil is disposed on at least one side of the dielectric layer, the copper foil is adhered to the dielectric layer with the first surface, and the copper foil has a zinc content ranging from 40 μg/dm² to 450 μg/dm², a nickel content ranging from 10 μg/dm² to 30 μg/dm², and a chromium content of no more than 1 μg/dm² at the first surface.

2. The copper-clad laminate of claim 1, wherein the copper foil has a zinc content ranging from 40 μg/dm² to 150 μg/dm² at the first surface.

3. The copper-clad laminate of claim 1, wherein the copper foil has a chromium content of no more than 0.5 μg/dm² at the first surface.

4. The copper-clad laminate of claim 1, wherein the first surface has a ten-point average roughness (Rz) of less than 0.5 μm.

5. The copper-clad laminate of claim 1, wherein the copper foil is disposed on each side of the dielectric layer and adhered to the dielectric layer with its first surface.

6. The copper-clad laminate of claim 1, wherein the dielectric layer comprises a dielectric material formed from a resin composition.

7. The copper-clad laminate of claim 2, wherein the dielectric layer comprises a dielectric material formed from a resin composition.

8. The copper-clad laminate of claim 3, wherein the dielectric layer comprises a dielectric material formed from a resin composition.

9. The copper-clad laminate of claim 6, wherein the resin composition is a thermosetting resin composition.

10. The copper-clad laminate of claim 7, wherein the resin composition is a thermosetting resin composition.

11. The copper-clad laminate of claim 8, wherein the resin composition is a thermosetting resin composition.

12. The copper-clad laminate of claim 9, wherein the thermosetting resin composition comprises a thermosetting component selected from the group consisting of an epoxy resin, a thermosetting phenolic resin, a thermosetting benzoxazine resin, a thermosetting polyphenylene ether resin, a thermosetting multi-functional vinyl aromatic copolymer, a thermosetting nitrogen-containing heterocyclic copolymer, and combinations thereof.

13. The copper-clad laminate of claim 10, wherein the thermosetting resin composition comprises a thermosetting component selected from the group consisting of an epoxy resin, a thermosetting phenolic resin, a thermosetting benzoxazine resin, a thermosetting polyphenylene ether resin, a thermosetting multi-functional vinyl aromatic copolymer, a thermosetting nitrogen-containing heterocyclic copolymer, and combinations thereof.

14. The copper-clad laminate of claim 11, wherein the thermosetting resin composition comprises a thermosetting component selected from the group consisting of an epoxy resin, a thermosetting phenolic resin, a thermosetting benzoxazine resin, a thermosetting polyphenylene ether resin, a thermosetting multi-functional vinyl aromatic copolymer, a thermosetting nitrogen-containing heterocyclic copolymer, and combinations thereof.

15. The copper-clad laminate of claim 6, wherein the resin composition further comprises a component selected from the group consisting of a hardener, a catalyst, an elastomer, a filler, a dispersing agent, a toughener, a viscosity modifying agent, a flame retardant, a coupling agent, and combinations thereof.

16. The copper-clad laminate of claim 7, wherein the resin composition further comprises a component selected from the group consisting of a hardener, a catalyst, an elastomer, a filler, a dispersing agent, a toughener, a viscosity modifying agent, a flame retardant, a coupling agent, and combinations thereof.

17. The copper-clad laminate of claim 8, wherein the resin composition further comprises a component selected from the group consisting of a hardener, a catalyst, an elastomer, a filler, a dispersing agent, a toughener, a viscosity modifying agent, a flame retardant, a coupling agent, and combinations thereof.

18. A printed circuit board, which is prepared from the copper clad laminate of claim 1.

19. A printed circuit board, which is prepared from the copper clad laminate of claim 2.

20. A printed circuit board, which is prepared from the copper clad laminate of claim 3.
